(19) United States
(12) Patent Application Publication
(10) Pub. No.: US 2016/0356835 A1
(43) Pub. Date: Dec. 8, 2016

(54) APPARATUS AND METHOD FOR DATA TRANSMISSION AND TESTING

(71) Applicant: John M. HORAN, Cork (IE)

(72) Inventor: John M. HORAN, Cork (IE)

(21) Appl. No.: 15/170,652

(22) Filed: Jun. 1, 2016

Related U.S. Application Data
(60) Provisional application No. 62/170,078, filed on Jun. 2, 2015.

(51) Int. Cl. G01R 31/01; H04L 27/01; H04N 7/10; G01R 31/08; H04N 5/775; H04B 3/04; H04B 3/46

(52) U.S. Cl. CPC G01R 31/01; H04B 3/04; H04L 27/01; H04B 3/46; G01R 31/083; H04N 5/775; H04N 7/108

(57) ABSTRACT

A signal compensating high-speed data cable connects a first device to a second device. The cable comprises a signal frequency-shaping device configured to provide a signal boost in the cable, wherein an equalizer circuit in the second device receives the boosted signal and the equalizer circuit outputs a desired frequency response to conform to a desired standard. A system and method for testing high-speed data cables is also described.

### BACKGROUND OF THE INVENTION

1. Technical Field

The present invention relates to communications and more particularly relates to cables suitable for relatively high-speed data transmission.

2. Background Art

High-speed data cables, or compact active cables, embed signal-processing technology directly into the cable structure to improve bandwidth performance and extend the capability of many communications standards including high-definition multimedia interface (“HDMI”), universal serial bus (“USB”), DisplayPort, Infiniband (“TB”), and others. In Compact Active cable solutions the embedded chip compensates for the data loss that occurs when very high-speed signals are transmitted over copper. This active boosting means that active cables can be made thinner, longer, faster, lighter and more compact than their passive equivalents.

Cables, for example an HDMI cable, have relatively limited data capacity or bandwidth, particularly for high frequency signals. This means that while a low frequency signal's energy will be passed mostly unaltered, the energy associated with a high frequency signal will generally be somewhat attenuated. The magnitude of this attenuation versus frequency in a cable provides a good measure of the quality of a cable and directly influences the quality of the data transmission in that cable. Maintaining high data quality is a difficult task, and is made more difficult by increased channel speed and cable length.

The problem with using long cables for transferring high data rate is that losses in a standard copper cable may create a signal to noise ratio at the far end of the cable that ultimately results in corrupt data transmission. Many companies use measurements of insertion loss versus frequency to test cables for compliance to particular standards. To accomplish this goal, a simple chart of loss threshold versus frequency, similar to the chart illustrated in FIG. 1, is often employed. If the deviation is significant, a particular cable may be unsuitable for certain applications so cable quality can be measured to see if the cable “passes” or “meets” the standards for a specific application.

If a measured cable has more attenuation or loss than the accepted threshold at a particular frequency, then the cable fails the test and would not be used for that specific application. To measure the loss data versus frequency, a device such as a vector network analyzer (“VNA”) may be used. While reasonably effective, the VNA is a relatively slow and somewhat expensive piece of equipment and, accordingly, is not generally considered suitable for production testing of cables.

Another known solution for testing cable quality is the practice of embedding a dedicated equalizer circuit in the cable. Such equalization has a variety of boost characteristics in order to cancel various losses in a wide spectrum of cable gauges, lengths and speeds. A known solution whereby each channel has an equalizer that can be individually tuned or programmed at production can solve some performance issues. The function of the equalizer can be described as the magnitude response of a system rolls off at higher frequencies, the equalizer counteracts this phenomenon by having a magnitude response that will increase with increasing frequency. However a problem in supplying any kind of equalization is delivering power to the equalization circuit. The current HDMI standard only allows for 5 mA current consumption from its 5V power supply. This 5 mA limit makes it difficult to deliver effective equalization solutions for any useful range of cable structures, thicknesses, lengths and speeds. With this limitation in mind, power can be harvested from the sink device (e.g. TV or monitor) through the output driver of the equalizer circuit. This power supply is then used to supply the equalizer and subsequent circuits needed to drive the data through the output driver. However, drawing power from the TV or monitor source and perform equalization in the cable itself is a difficult and complex exercise, especially at data speeds in excess of 3 GBps which are now required by the HDMI 2.0 standard.

Accordingly, without improvements in the state of the art for cables compliant with the HDMI 2.0 standard, high-speed data transmission will continue to be sub-optimal.

### BRIEF SUMMARY OF THE INVENTION

According to the invention there is provided, as set forth in the appended claims, a high-speed data cable for connecting a first device to a second device, the cable comprising: a signal frequency shaping device configured to provide a signal boost in the cable, wherein an equalizer circuit in the second device receives the boosted signal; and the equalizer circuit outputs a desired frequency response to conform with a desired standard.

The most preferred embodiments of the present invention involve embedding a signal frequency shaping device or chip in the cable that tailors the losses in the cable in a manner that makes it easy for the receiving device to acquire the transferred data. The resultant cable is called an “active cable.” The advantage of the implementation is that less power is required in the cable to enable high-speed data transfer across the cable.

In at least one preferred embodiment of the present invention, the signal frequency-shaping device is arranged in cascade with the equalizer circuit in the second device during use and adapted to counteract any losses in the cable to conform to the desired standard. In one embodiment the desired standard comprises the HDMI standard.

In at least one preferred embodiment of the present invention, the signal frequency-shaping device comprises an integrated 15 circuit.

In at least one preferred embodiment of the present invention, the signal frequency-shaping device comprises a one-time programmable memory to provide the cable with a signal boost with a particular loss profile in the cable.

In at least one preferred embodiment of the present invention, the signal frequency-shaping device comprises a one-time programmable memory such that DC offset removal and gain calibration of the device can take place. It will be appreciated by those skilled in the art that fuses can also be used instead of the one-time programmable memory. This can be achieved by the signal frequency shaping device or integrated circuit having a number of current sources that can be controlled in a differential stage circuit and allow cancellation of the offset in the gain stage. A number of different nodes can be configured to allow different load resistance selection that allows the gain of the stage to be tuned or programmed depending on the cable characteristics.

In at least one preferred embodiment of the present invention, there is provided a system for testing the performance of a high speed data cable, the system comprising: a module adapted to generate a range of signals with different frequencies and be sent down the high speed data cable at one end; a measurement module positioned at the other end of the cable adapted to measure power of received signals; and a microcontroller configured to compute the power loss at each frequency for each signal and compare against an acceptable power loss level to determine a pass or fail condition.

In at least one preferred embodiment of the present invention, the measurement module comprises a programmable phased-locked loop (“PLL”) module.

In at least one preferred embodiment of the present invention, the measurement module comprises a power or peak-to-peak voltage measurement IC.

In at least one preferred embodiment of the present invention, the microcontroller computes the power loss at each frequency by dividing the output power by the known input power.

It will be appreciated by those skilled in the art that the various preferred embodiments of the present invention described herein can readily accommodate 6 Gbps, the speed that is generally required to achieve acceptable HDMI 2.0 compatibility.

In another preferred embodiment of the present invention, there is provided a method for testing the performance of a high speed data cable, the method comprising the steps of: generating a range of signals with different frequencies and be sent down the high speed data cable at one end; measuring at the other end of the cable adapted to measure power of received signals; and computing the power loss at each frequency for each signal and compare against an acceptable power loss level to determine a pass or fail condition.

There is also provided a computer program comprising program instructions for causing a computer program to carry out the above method that may be embodied on a record medium, carrier signal or read-only memory.

### BRIEF DESCRIPTION OF THE FIGURES

The preferred embodiments of the present invention will hereinafter be described in conjunction with the appended drawings, wherein like designations denote like elements, and:

FIG. 1 illustrates a simple chart plotting loss threshold versus frequency for testing the quality of a cable in accordance with a preferred exemplary embodiment of the present invention;

FIG. 2 is a block diagram of a cable in accordance with a preferred exemplary embodiment of the present invention;

FIG. 3 illustrates a gain of reference standard for the HDMI standard;

FIG. 4 is a more detailed block diagram of the cable shown in FIG. 2 according to a preferred exemplary embodiment of the present invention; and

FIG. 5 illustrates a system for testing the performance of a high-speed data cable in accordance with another preferred exemplary embodiment of the present invention.

### DETAILED DESCRIPTION OF THE INVENTION

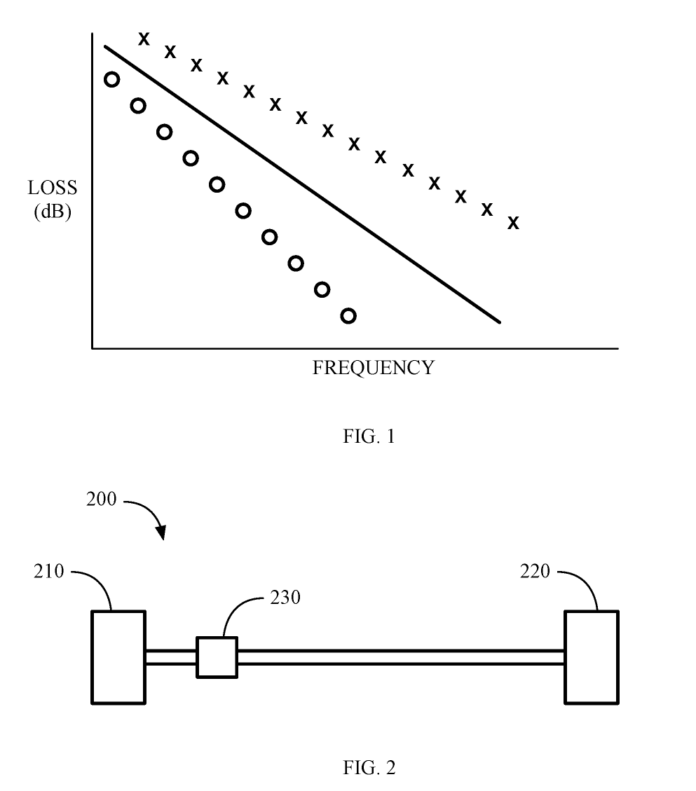

Referring now to FIG. 2 a high-speed data cable 200 in accordance with a preferred embodiment of the present invention is depicted. Cable 200 is shown connecting a first device 210 to a second device 220. The cable has a signal frequency-shaping device 230 configured to alter the loss vs. frequency profile of the signal in the cable. The signal can be altered in a number of ways. For example, a boost can be provided at high frequencies or the signal can be attenuated at lower frequencies. An equalizer circuit (not shown this FIG.) in second device 220 receives the altered signal and the equalizer circuit outputs a desired frequency response to conform to a desired standard. Signal frequency-shaping device 230 alters the signal in the cable to ‘flatten’ the frequency response to a desired level so as to enable the equalizer in second device 220 to recover the signal. In many applications, second device 220 is typically a TV or monitor receiver.

The most preferred embodiments of the present invention recognize and leverage the fact that the standard for HDMI specifies that the receiver (TV) can recover the data sufficiently well even in the presence of significant losses. Signal frequency-shaping device 220 has been designed to use this fact to reduce the overall power consumed by signal frequency-shaping device 220 to less than that specified by the HDMI standard of 25 mW.

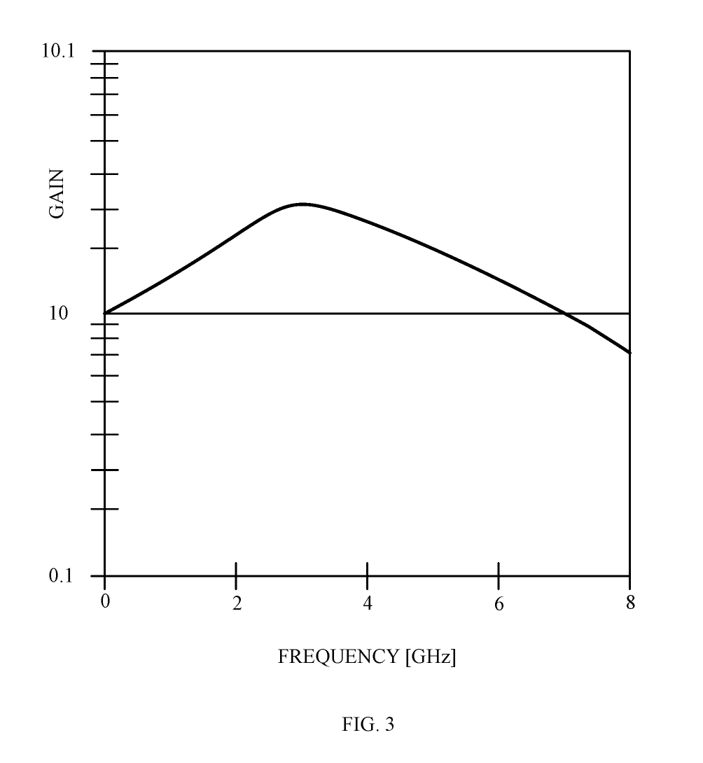

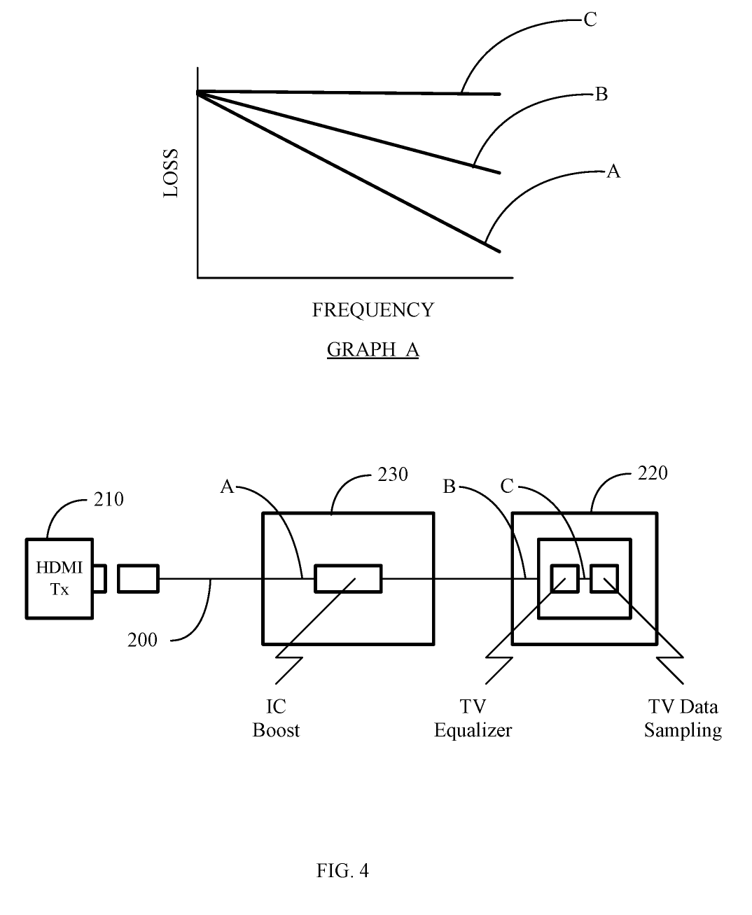

Referring now to FIG. 3 and FIG. 4, the HDMI Forum (hdmi.org) has promulgated a standard that guarantees a minimum level of equalization in a device, such as a TV or monitor, with what is called a reference cable equalizer. FIG. 3 illustrates a gain profile with respect to frequency that conforms generally to the HDMI standard.

Referring now to FIG. 4, a block diagram of the resultant signal showing the invention from FIG. 2 in operation using Graph A to plot frequency vs. loss in a cable. The data signal at point A is represented in the frequency domain (Graph A) and shows significant loss over frequency. At point B the loss versus frequency shows that frequency shaping from the embedded signal frequency shaping device or integrated circuit 230 has been added and the loss versus frequency has been markedly improved.

Finally, at receiver device 220, a TV equalizer in receiver device 220 alters the signal to the point where there is no significant change in the loss versus frequency, essentially restoring the signal to its original state. The signal will now have an “open eye” and is ready for sampling by the receiver. An open eye is a measure of the data quality and can be measured in terms of eye closure/opening within Eye Diagrams. An open eye is desirable in the signal to ensure correct processing of the signal. In summary, the cables of the most preferred embodiments of the present invention are configured to add sufficient boost to the cable with an embedded signal frequency shaping device or integrated circuit such that the loss in the cable approximately equals the sum of the boost added by the signal frequency shaping device or integrated circuit and the reference equalizer in the TV. In other words:

[Loss in Cable˜Boost from In-cable IC+Reference cable equalizer]

In at least one preferred exemplary embodiment of the present invention, EQ. 1 can be further refined to:

C=[loss in the cable+the signal frequency shaping device+the reference cable equalizer]

where “C” is a constant is in the range of 0 db to −16 dBs This allows for the fact that the frequency shaping device can effectively implement low frequency attenuation instead of high frequency gain to achieve the desired signal stability.

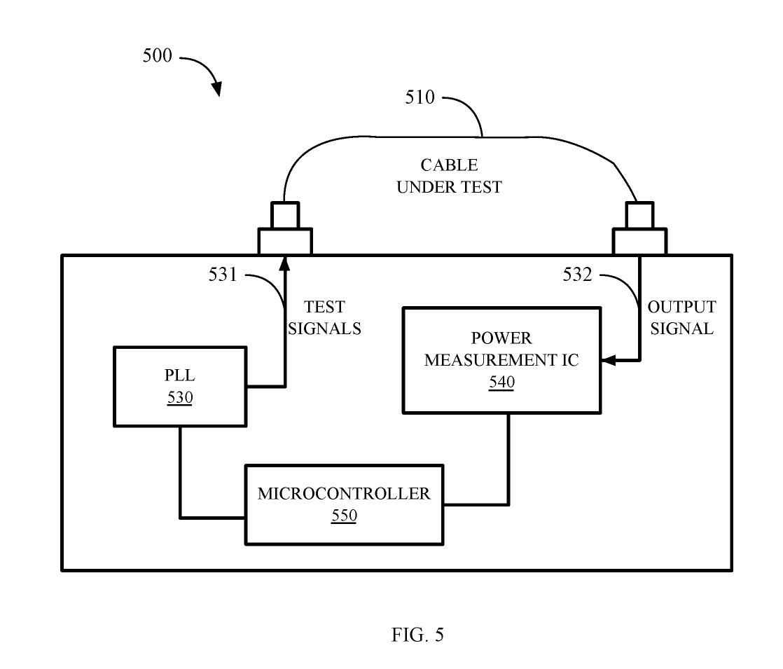

Referring now to FIG. 5, a system 500 for testing the performance of a high-speed data cable 510 according to at least one preferred embodiment of the present invention is illustrated. System 500 comprises: a PLL 530 used to generate a range of signals 531 at different frequencies with signals 531 being transmitted via cable 510; a power measurement (e.g., peak-to-peak voltage measurement) IC 540 to measure power that passed through cable 510; a microcontroller 550 configured to control PLL b. accumulate the output power versus frequency from the power measurement IC. c. compute the power loss at each frequency. In the most preferred embodiments of the present invention, the power loss is calculated by dividing the output power by the known input power. System 500 can be used to ascertain the power loss in cable 510 at each desired frequency level. System 500 will then check the power loss at each frequency against a table of pre-determined acceptable losses for each frequency and then report a result (e.g., “pass” or “fail”) based on the table of acceptable losses.

Another addition to system 500 is that it checks that the appropriate connectivity exits between all wires in the cable. To do this microcontroller output voltages on particular wires and checks that no leakage happens to other wires.

In summary system 500 operates to complete at least the loss measurement system method described above along with a basic connectivity test. It will be appreciated that the invention helps the production of copper cables. In particular it enables the production of longer or thinner cables.

The various preferred exemplary embodiments in the invention described with reference to the drawings comprise a computer apparatus and/or processes performed in a computer apparatus. However, the invention also extends to computer programs, particularly computer programs stored on or in a carrier adapted to bring the invention into practice. In particular computer programs for controlling the system and method as hereinbefore described. The program may be in the form of source code, object code, or a code intermediate source and object code, such as in partially compiled form or in any other form suitable for use in the implementation of the method according to the invention. The carrier may comprise a storage medium such as ROM, e.g. CD ROM, or magnetic recording medium, e.g. a floppy disk or hard disk. The carrier may be an electrical or optical signal that may be transmitted via an electrical or an optical cable or by radio or other means.

Additionally, at least a portion of the systems, methodologies and techniques described with respect to the exemplary embodiments of present disclosure can incorporate a machine, such as, but not limited to, computer system, or any other computing device within which a set of instructions, when executed, may cause the machine to perform any one or more of the methodologies or functions discussed above. The machine may be configured to facilitate various operations conducted by the systems disclosed herein. For example, the machine may be configured to, but is not limited to, assist the systems by providing processing power to assist with processing loads experienced in the systems, by providing storage capacity for storing instructions or data traversing the systems, or by assisting with any other operations conducted by or within the systems.

Dedicated hardware implementations including, but not limited to, application specific integrated circuits, programmable logic arrays and other hardware devices can likewise be constructed to implement the system and methods described herein. Applications that may include the apparatus and systems of various embodiments broadly include a variety of electronic and computer systems. Some embodiments implement functions in two or more specific interconnected hardware modules or devices with related control and data signals communicated between and through the modules, or as portions of an application-specific integrated circuit. Thus, the example system is applicable to software, firmware, and hardware implementations.

In accordance with various exemplary embodiments of the present disclosure, the methods described herein are intended for operation as software programs running on a computer processor. Furthermore, software implementations can include, but not limited to, distributed processing or component/object distributed processing, parallel processing, or virtual machine processing can also be constructed to implement the methods described herein.

In the specification the terms “comprise, comprises, comprised and comprising” or any variation thereof and the terms include, includes, included and including” or any variation thereof are considered to be totally interchangeable and they should all be afforded the widest possible interpretation and vice versa.

From the foregoing description, it should be appreciated that the cable and associated method for testing cables disclosed herein presents significant benefits that would be apparent to one skilled in the art. Furthermore, while multiple embodiments have been presented in the foregoing description, it should be appreciated that a vast number of variations in the embodiments exist. Lastly, it should be appreciated that these embodiments are preferred exemplary embodiments only and are not intended to limit the scope, applicability, or configuration of the invention in any way. Rather, the foregoing detailed description provides those skilled in the art with a convenient road map for implementing a preferred exemplary embodiment of the invention, it being understood that various changes may be made in the function and arrangement of elements described in the exemplary preferred embodiment without departing from the spirit and scope of the invention as set forth in the appended claims.

1. A high speed data cable for connecting a first device to a second device, the cable comprising:
an embedded signal frequency shaping device configured to provide a signal boost in the cable, wherein an equalizer circuit in the second device receives the boosted signal; and
a desired frequency response output from the equalizer circuit so as to conform to a desired standard.

2. The high speed data cable of claim 1 wherein the signal frequency shaping device is arranged in cascade with the equalizer circuit in the second device during use and is further adapted to counteract any losses in the cable to conform with the desired standard.

3. The high-speed data cable of claim 1 wherein the desired standard comprises the HDMI standard.

4. The high-speed data cable of claim 2 wherein the desired standard comprises the HDMI standard.

5. The high-speed data cable of claim 1 wherein the signal frequency-shaping device comprises an integrated circuit and wherein the desired standard comprises the HDMI standard.

6. The high-speed data cable of claim 1 wherein the signal frequency-shaping device comprises a one-time programmable memory to provide the cable with a signal boost with a particular loss profile in the cable.

7. The high-speed data cable of claim 1 wherein the signal frequency-shaping device comprises a one-time programmable memory such that DC offset removal and gain calibration of the device can take place.

8. The high-speed data cable of claim 1 wherein the first device provides 5 mA or less of power to provide the signal boost.

9. The high-speed data cable of claim 1 wherein the boost from the signal frequency-shaping device plus the boost from the equalizer in the second device is selected to be substantially equal to the projected loss in the cable.

10. The high-speed data cable of claim 1 wherein the boost from the signal frequency-shaping device plus the boost from the equalizer in the second device plus the projected loss in the cable is selected to result in a substantially flat amplitude versus frequency response.

11. A system for testing the performance of a high-speed data cable, the system comprising:
a signal-generating module communicatively coupled to a first end of the high-speed data cable, the signal-generating module:
generating a plurality of signals with a plurality of different frequencies; and
transmitting the plurality of signals via the high-speed data cable;
a measurement module communicatively coupled to a second end of the high-speed data cable, the measurement module receiving a measuring a power level associated with the plurality of signals generated by the signal-generating module; and
a microcontroller, the microcontroller:
computing a power loss at for each of the plurality of signals; and
comparing the power loss against an acceptable power loss level to determine a pass or fail condition for the high-speed data cable.

12. The system of claim 11 wherein the module comprises programmable phase-locked loop module.

13. The system of claim 11 wherein the measurement module comprises at least one of:
a power measurement integrated circuit; and
a peak-to-peak voltage measurement integrated circuit.

14. The system of claim 11 wherein the measurement module comprises at least one of:
a power measurement integrated circuit; and
a peak-to-peak voltage measurement integrated circuit.

15. The system of claim 11 wherein the microcontroller computes the power loss at each frequency by dividing the output power by the known input power.

16. The system of claim 12 wherein the microcontroller computes the power loss at each frequency by dividing the output power by the known input power.

17. The system of claim 13 wherein the microcontroller computes the power loss at each frequency by dividing the output power by the known input power.
